(19) United States
(12) Patent Application Publication
(10) Pub. No.: US 2023/0227609 A1
(43) Pub. Date: Jul. 20, 2023

(54) POLYIMIDE FILM, AND METAL-CLAD LAMINATE

(71) Applicant: NITTO DENKO CORPORATION, Ibaraki-shi, Osaka (JP)

(72) Inventor: Kei MISHIMA, Ibaraki-shi, Osaka (JP)

(21) Appl. No.: 18/009,433

(22) PCT Filed: May 24, 2021
(86) PCT No.: PCT/JP2021/019545

§ 371 Date: Dec. 9, 2022

(30) Foreign Application Priority Data
Jun. 9, 2020 (JP) 2020-100050

(51) Int. Cl. C08G 73/10; C08J 5/18; H05K 1/03

(52) U.S. Cl. CPC C08G 73/1075; C08J 5/18; H05K 1/0346; H05K 2201/0154; C08J 2379/08

(57) ABSTRACT

A polyimide film is a reaction product of a diamine component and an acid dianhydride component. The diamine component contains p-phenylenediamine, a first aromatic diamine, and a second aromatic diamine. The first aromatic diamine and the second aromatic diamine are different from each other and represented by the following formula (1):

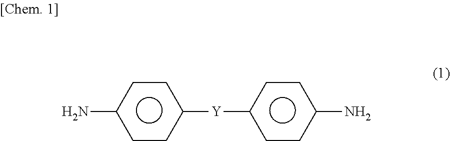

In the diamine component, each of a molar fraction of the p-phenylenediamine, a molar fraction of the first aromatic diamine, and a molar fraction of the second aromatic diamine is 10% by mole or more and 70% by mole or less. The acid dianhydride component contains an acid dianhydride containing an aromatic ring.

### TECHNICAL FIELD

Conventionally, a copper-clad laminate including a copper foil and a polyimide film disposed on its surface has been known to be used in various fields. A circuit board in which a copper pattern is formed from the copper foil of the copper-clad laminate is required to suppress degradation of electrical properties (specifically, dielectric properties) even though being humidified. Therefore, the polyimide film is required to suppress degradation of dielectric properties when humidified, that is, to have low hygroscopic dielectric properties.

For example, there has been proposed a polyimide film obtained by allowing paraphenylenediamine (p-PDA) and 4,4-diaminodiphenylether (ODA) to react with 3,3′4,4′-biphenyltetracarboxylic acid dianhydride (BPDA) (cf. Patent Document 1).

### CITATION LIST

### Patent Document

Patent Document 1: Japanese Unexamined Patent Publication No. 2004-137486

### SUMMARY OF THE INVENTION

### Problem to be Solved by the Invention

However, there is a limit to improvement of low hygroscopic dielectric properties with the polyimide film described in Patent Document 1.

The present invention is to provide a polyimide film and a metal-clad laminate that are excellent in low hygroscopic dielectric properties.

### Means for Solving the Problem

The present invention (1) includes a polyimide film being a reaction product of a diamine component and an acid dianhydride component, in which the diamine component contains p-phenylenediamine; a first aromatic diamine; and a second aromatic diamine, the first aromatic diamine and the second aromatic diamine are different from each other and represented by the following formula (1):

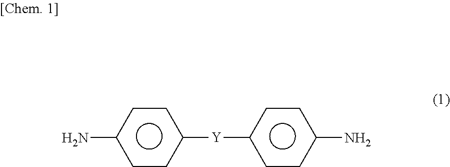

(where Y represents at least one selected from the group consisting of a single bond, —O—, —COO—, —S—, CH₂—, —CH(CH₃)—, —C(CH₃)₂—, —CO—, —SO₂—, —NH—, and —NHCO—), in the diamine component, each of a molar fraction of the p-phenylenediamine, a molar fraction of the first aromatic diamine, and a molar fraction of the second aromatic diamine is 10% by mole or more and 70% by mole or less, and the acid dianhydride component contains an acid dianhydride including an aromatic ring.

The present invention (2) includes the polyimide film described in (1), in which the molar fraction of the p-phenylenediamine is 20% by mole or more.

The present invention (3) includes the polyimide film described in (1) or (2), in which the molar fraction of the first aromatic diamine or the second aromatic diamine is 50% by mole or less.

The present invention (4) includes a metal-clad laminate including a polyimide film described in any one of (1) to (3); and a metal foil disposed on one surface in a thickness direction of the polyimide film.

### Effects of the Invention

The polyimide film and the metal-clad laminate according to the present invention are excellent in low hygroscopic dielectric properties.

### BRIEF DESCRIPTION OF THE DRAWING

FIG. 1 is a cross-sectional view of one embodiment of a metal-clad laminate of the present invention.

### DESCRIPTION OF THE EMBODIMENTS

### <Polyimide Film>

The polyimide film of the present invention is a reaction product of a diamine component and an acid dianhydride component. More particularly, the polyimide film is a condensation polymerization product of a diamine component and an acid dianhydride component.

The diamine component contains p-phenylenediamine, a first aromatic diamine, and a second aromatic diamine.

P-phenylenediamine may be abbreviated as PDA. A molar fraction of PDA in the diamine component will be described later.

The first aromatic diamine and the second aromatic diamine have mutually different chemical structural formulae. On the other hand, the first aromatic diamine and the second aromatic diamine are both represented by the following formula (1):

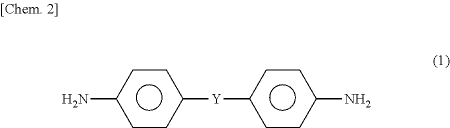

(where Y represents at least one selected from the group consisting of a single bond, —O—, —S—, CH₂—, —CH(CH₃)—, —C(CH₃)₂—, —CO—, —SO₂—, —NH—, and —NHCO—).

An amino group (—NH₂) is bonded to a carbon atom located at the para position with respect to a carbon atom to be bonded to Y in an aromatic ring.

Specifically, as the first aromatic diamine and the second aromatic diamine, 4,4′-oxydianiline in which Y in the formula (1) is —O—, 4-aminophenyl-4-aminobenzoate in which Y in formula (1) is —COO—, 4,4′-methylenedianiline in which Y in the formula (1) is —CH₂—, and bis(4-aminophenyl)sulfone in which Y in the formula (1) is —SO₂— are used.

Preferably, the first aromatic diamine is 4,4′-oxydianiline, and the second aromatic diamine is 4-aminophenyl-4-aminobenzoate. 4,4′-oxydianiline may be abbreviated as ODA. 4-aminophenyl-4-aminobenzoate may be abbreviated as APAB.

### <Molar Fractions of Diamines>

The molar fractions of PDA, the first aromatic diamine, and the second aromatic diamine in the diamine component are each 10% by mole or more and 70% by mole or less. When the molar fractions of PDA, the first and second aromatic diamines are each outside the above range, low hygroscopic dielectric properties of the polyimide film are degraded.

### <Suitable Molar Fractions of Diamines>

The molar fraction of PDA in the diamine component is preferably 15% by mole or more, more preferably 20% by mole or more, even more preferably 25% by mole or more, particularly preferably 30% by mole or more, most preferably 40% by mole or more. When the molar fraction of PDA is the above-described lower limit or more, it is possible to reduce a coefficient of thermal expansion of the polyimide film. The molar fraction of PDA in the diamine component is preferably 65% by mole or less, more preferably 60% by mole or less. When the molar fraction of PDA is the above-described upper limit or less, it is possible to improve low hygroscopic dielectric properties of the polyimide film.

The molar fraction of the first aromatic diamine or the second aromatic diamine in the diamine component is preferably 55% by mole or less, more preferably 50% by mole or less. When the molar fraction of the first aromatic diamine or the second aromatic diamine in the diamine component is the above-described upper limit or less, it is possible to reduce the coefficient of thermal expansion. Therefore, it is possible to reduce warpage of a metal-clad laminate in which the polyimide film is laminated on a metal foil.

When the first aromatic diamine is ODA and the second aromatic diamine is APAB, the molar fraction of the first aromatic diamine in the diamine component is preferably 55% by mole or less, more preferably 50% by mole or less, and the molar fraction of the second aromatic diamine in the diamine component is preferably 45% by mole or less, more preferably 40% by mole or less.

When the diamine component contains PDA, the first aromatic diamine, and the second aromatic diamine alone, the total molar fraction of the first and second aromatic diamines in the diamine component is the remainder of the molar fraction of PDA in the diamine component, and specifically, for example, 30% by mole or more, preferably 35% by mole or more, and for example, 90% by mole or less, preferably 85% by mole or less, more preferably 80% by mole or less, even more preferably 70% by mole or less, particularly preferably 60% by mole or less. The total molar fraction of the first and second aromatic diamines in the diamine component is, for example, 35% by mole or more, preferably 40% by mole or more.

The total mole part of the first aromatic diamine and the second aromatic diamine with respect to 100 parts by mole of PDA is, for example, 10 parts by mole or more, preferably 25 parts by mole or more, more preferably 50 parts by mole or more, and for example, 1000 parts by mole or less, preferably 500 parts by mole or less, more preferably 200 parts by mole or less, even more preferably 100 parts by mole or less.

When the first aromatic diamine is ODA and the second aromatic diamine is APAB, the mole part of the second aromatic diamine with respect to 100 parts by mole of the first aromatic diamine is, for example, 25 parts by mole or more, preferably 50 parts by mole or more, more preferably 75 parts by mole or more, and for example, 300 parts by mole or less, preferably 200 parts by mole or less, more preferably 150 parts by mole or less.

The diamine component may contain, for example, an aliphatic amine and the like as other diamines except the above-described PDA, first aromatic diamine, and second aromatic diamine Preferably, the diamine component does not contain other diamines, but contains the above-described PDA, first and second aromatic diamines alone.

### <Acid Dianhydride Component>

The acid dianhydride component contains an acid dianhydride containing an aromatic ring. Examples of the acid dianhydride containing an aromatic ring include aromatic tetracarboxylic acid dianhydride. Examples of the aromatic tetracarboxylic acid dianhydride include benzene tetracarboxylic acid dianhydride such as benzene-1,2,4,5-tetracarboxylic acid dianhydride (also known as pyromellitic acid dianhydride); benzophenone tetracarboxylic acid dianhydride such as 3,3′-4,4′-benzophenone tetracarboxylic acid dianhydride; biphenyl tetracarboxylic acid dianhydride such as 3,3′-4,4′-biphenyl tetracarboxylic acid dianhydride, 2,2′-3,3′-biphenyl tetracarboxylic acid dianhydride, 2,3,3′,4′-biphenyl tetracarboxylic acid dianhydride, and 3,3′4,4′-diphenylether tetracarboxylic acid dianhydride; diphenylsulfone tetracarboxylic acid dianhydride such as 3,3′-4,4′-diphenylsulfone tetracarboxylic acid dianhydride; and naphthalene tetracarboxylic acid dianhydride such as 2,3,6,7-naphthalene tetracarboxylic acid dianhydride, 1,2,5,6-naphthalene tetracarboxylic acid dianhydride, 1,2,4,5-naphthalene tetracarboxylic acid dianhydride, and 1,4,5,8-naphthalene tetracarboxylic acid dianhydride. These can be used alone or in combination. Preferably, biphenyl tetracarboxylic acid dianhydride is used, more preferably, 3,3′-4,4′-biphenyl tetracarboxylic acid dianhydride is used.

The acid dianhydride component may contain other acid dianhydrides except the acid dianhydride containing an aromatic ring. Preferably, the acid dianhydride component does not contain other acid dianhydrides, but contains the acid dianhydride containing an aromatic ring alone.

A ratio of the diamine component to the acid dianhydride component is adjusted so that the molar amount of the amino group (—NH₂) of the diamine component is, for example, equal to the molar amount of an acid anhydride group (—CO—O—CO—) of the acid anhydride component.

### <Production Method>

The polyimide film is obtained by allowing the diamine component and the acid dianhydride component to react with each other. This reaction is, though not limited to, polycondensation, and as a method thereof, for example, a two-step method through a polyamic acid is used.

For example, the diamine component and an organic solvent are mixed to prepare a diamine component solution. The organic solvent is not particularly limited, and examples thereof include polar aprotic solvents such as N-methylpyrrolidone (NMP), dimethylformamide, and dimethyl sulfoxide; ether solvents; ester solvents; aliphatic hydrocarbon solvents; and aromatic hydrocarbon solvents. Preferably, a polar aprotic solvent is used. The organic solvent is mixed in an amount of, for example, 100 parts by mass or more and, for example, 1,000 parts by mass or less, with respect to 100 parts by mass of the diamine component. A percentage of the diamine component in the diamine component solution is, for example, 1% by mass or more and, for example, 10% by mas or less.

Then, the diamine component solution and the acid dianhydride component are mixed to prepare a mixture. At this time, an appropriate amount of the organic solvent can be added to the mixture as required.

Thereafter, the resulting mixture is heated. This allows the diamine component and the acid dianhydride component to be subjected to a ring-opening polyaddition reaction, so that a polyamic acid solution is prepared. The heating temperature is, for example, 50° C. or more and 100° C. or less.

Thereafter, the polyamic acid solution is applied to a base material, and the organic solvent is then removed, followed by heating the resulting product. This allows the polyamic acid to be subjected to cyclodehydration reaction, so that the polyamic acid is amidated.

The base material has a sheet shape extending in a direction orthogonal to the thickness direction. As the base material, a metal foil, a resin sheet, or the like is used.

To remove the organic solvent, the polyamic acid solution is heated at a temperature of, for example, 100° C. or more and 150° C. or less. To amidate the polyamic acid, the polyamic acid is heated, for example, under vacuum at a temperature of, for example, 300° C. or more and 450° C. or less, for example, for 1 hour or more, preferably 2 hours or more.

Thus, a polyimide film disposed on one surface in the thickness direction of the base material is obtained.

Thereafter, the base material is removed.

As a result, a polyimide film is obtained.

The thickness of the polyimide film is not particularly limited, and is, for example, 10 μm or more, preferably 50 μm or more, and for example, 1,000 μm or less, preferably 500 μm or less.

### <Properties of Polyimide Film>

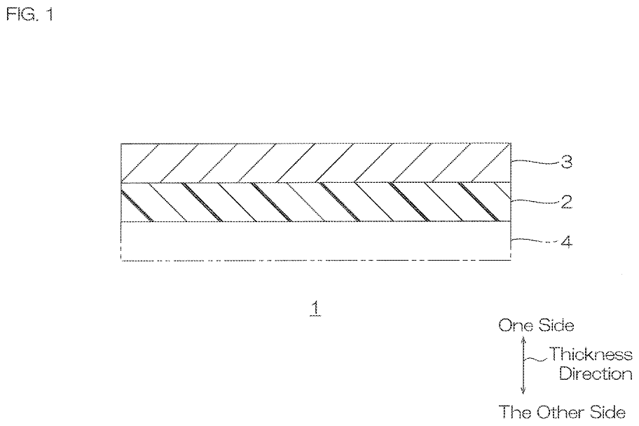

After being immersed in water at 25° C. for 24 hours, the polyimide film has a dielectric loss tangent of, for example, less than 0.010, preferably 0.0090 or less, more preferably 0.0085 or less, even more preferably 0.0080 or less, particularly preferably 0.0075 or less. When the dielectric loss tangent of the polyimide film after immersion is the above-described upper limit or less, a circuit board obtained by patterning a metal foil of a metal-clad laminate (to be described later, cf: FIG. 1) including a polyimide film can suppress degradation of electrical properties even though being humidified. The dielectric loss tangent of the polyimide film after immersion is, for example, 0.0001 or more. A measurement method of the dielectric loss tangent of the polyimide film after immersion will be described in detail in Example below.

The polyimide film has a coefficient of thermal expansion of, for example, 50.0 ppm/K or less, preferably 45.0 ppm/K or less, more preferably 40.0 ppm/K or less, even more preferably 35.0 ppm/K or less, particularly preferably 30.0 ppm/K or less. When the coefficient of thermal expansion of the polyimide film is the above-described upper limit or less, it is possible to suppress warpage of the metal-clad laminate including the polyimide film. The coefficient of thermal expansion of the polyimide film is, for example, 1.0 ppm/K or more. A measurement method of the coefficient of thermal expansion of the polyimide film will be described in detail in Example below.

Next, the metal-clad laminate including the polyimide film will be described with reference to FIG. 1.

A metal-clad laminate 1 includes a polyimide film 2, a metal foil 3 disposed on one surface in the thickness direction of the polyimide film 2.

The polyimide film 2 forms the other surface in the thickness direction of the metal-clad laminate 1.

The metal foil 3 forms one surface in the thickness direction of the metal-clad laminate 1. The metal foil 3 comes in contact with the entire one surface in the thickness direction of the polyimide film 2. Examples of a material of the metal foil include copper, iron, and stainless steel, and preferably, copper is used. The thickness of the metal foil 3 is, for example, 10 μm or more, preferably 50 μm or more, and for example, 1,000 μm or less, preferably 500 μm or less.

In the production method of the polyimide film, the metal foil 3 as a base material is not removed but is left. As a result, the metal-clad laminate 1 sequentially including the polyimide film 2 and the metal foil 3 at one side in the thickness direction is obtained.

The thickness of the metal-clad laminate 1 is, for example, 20 μm or more, preferably 100 μm or more, and for example, 2,000 μm or less, preferably 1,000 μm or less.

### <Function and Effects>

Since in the polyimide film, the diamine component contains p-phenylenediamine, a first aromatic diamine, and a second aromatic diamine in a molar fraction of 10% by mole or more and 70% by mole or less, and the acid dianhydride component contains an acid dianhydride containing an aromatic ring, it is excellent in low hygroscopic dielectric properties.

Since the metal-clad laminate shown in FIG. 1 includes the above-described polyimide film 2, it is excellent in low hygroscopic dielectric properties.

Therefore, a circuit board (not shown) having a metal pattern formed from the metal foil 3 in the metal-clad laminate 1 can suppress degradation of electrical properties (specifically, dielectric properties) even though being humidified.

In the above-described polyimide film 2, when the molar fraction of PDA in the diamine component is 20% by mole or more, it is possible to reduce a coefficient of thermal expansion of the polyimide film 2.

Further, in the above-described polyimide film 2, when the molar fraction of the first aromatic diamine or the second aromatic diamine in the diamine component is 50% by mole or less, it is possible to reduce the coefficient of thermal expansion.

### Modified Example

In the modified example, the same reference numerals are provided for members and steps corresponding to each of those in one embodiment, and their detailed description is omitted. Further, the modified example can achieve the same function and effect as that of one embodiment unless otherwise specified. Furthermore, one embodiment and the modified example thereof can be appropriately used in combination.

As shown in phantom lines in FIG. 1, the metal-clad laminate 1 may further include a second metal foil 4 disposed on the other surface in the thickness direction of the polyimide film 2. The second metal foil 4 has the same configuration as the above-described metal foil 3. In the metal-clad laminate 1, the second metal foil 4, the polyimide film 2, and the metal foil 3 are sequentially disposed toward one side in the thickness direction.

An acid dianhydride component solution may be prepared by mixing an acid dianhydride component and an organic solvent, followed by mixing of a diamine component with the acid dianhydride component solution.

### Example

The specific numerical values in mixing ratio (content ratio), property value, and parameter used in the following description can be replaced with upper limit values (numerical values defined as “or less” or “below”) or lower limit values (numerical values defined as “or more” or “above”) of corresponding numerical values in mixing ratio (content ratio), property value, and parameter described in the above-described “DESCRIPTION OF THE EMBODIMENTS”. The “parts” and “%” are based on mass unless otherwise specified in the following description.

### Example 1

Under a stream of nitrogen, 14.27 g of PDA, 8.81 g of ODA, 10.04 g of APAB, and 470 mL of NMP were added to a 1000 mL separable flask, and the mixture was stirred at 40° C. for 20 minutes to prepare a diamine solution. Subsequently, 64.73 g of 3,3′-4,4′-biphenyl tetracarboxylic acid dianhydride and 21 mL of dehydrated NMP were further added thereto, and the resulting mixture was stirred at 80° C. The stirring was then stopped, and the mixture was allowed to cool to give a brown polyamic acid solution. The polyamic acid solution was applied to a copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Example 2

Under a stream of nitrogen, 2.16 g of PDA, 2.00 g of ODA, 4.57 g of APAB, and 105 mL of dehydrated NMP were added to a 300 mL separable flask, and the mixture was stirred at 40° C. for 20 minutes. Subsequently, 14.71 g of 3,3′-4,4′-biphenyl tetracarboxylic acid dianhydride and 13 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Example 3

Under a stream of nitrogen, 0.97 g of PDA, 3.60 g of ODA, 4.11 g of APAB, and 100 mL of dehydrated NMP were added to a 300 mL separable flask, and the mixture was stirred at 40° C. for 20 minutes. Subsequently, 13.24 g of 3,3′-4,4′-biphenyl tetracarboxylic acid dianhydride and 10 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Example 4

Under a stream of nitrogen, 1.08 g of PDA, 6.01 g of ODA, 2.28 g of APAB, and 100 mL of dehydrated NMP were added to a 300 mL separable flask, and the mixture was stirred at 40° C. for 20 minutes. Subsequently, 14.71 g of 3,3′-4,4′-biphenyl tetracarboxylic acid dianhydride and 21 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Example 5

Under a stream of nitrogen, 2.70 g of PDA, 3.00 g of ODA, 2.28 g of APAB, and 100 mL of dehydrated NMP were added to a 300 mL separable flask, and the mixture was stirred at 40° C. for 20 minutes. Subsequently, 14.71 g of 3,3′-4,4′-biphenyl tetracarboxylic acid dianhydride and 15 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Example 6

Under a stream of nitrogen, 0.65 g of PDA, 4.21 g of ODA, 7.53 g of APAB, and 141 mL of dehydrated NMP were added to a 300 mL separable flask, and the mixture was stirred at 40° C. for 20 minutes. Subsequently, 17.65 g of 3,3′-4,4′-biphenyl tetracarboxylic acid dianhydride and 10 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Example 7

Under a stream of nitrogen, 0.65 g of PDA, 6.61 g of ODA, 4.79 g of APAB, and 139 mL of dehydrated NMP were added to a 300 mL separable flask, and the mixture was stirred at 40° C. for 20 minutes. Subsequently, 17.65 g of 3,3′-4,4′-biphenyl tetracarboxylic acid dianhydride and 10 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Comparative Example 1

The amount 129.77 g of PDA, 60.07 g of ODA, and 2943 mL of NMP were added to a 3000 mL separable flask, and the mixture was stirred at 25° C. for 20 minutes. Subsequently, 441.33 g of 3,3′-4,4′-biphenyl tetracarboxylic acid dianhydride was added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Comparative Example 2

Under a stream of nitrogen, 12.01 g of ODA and 140 mL of dehydrated NMP were added to a 300 mL separable flask, and the mixture was stirred at 40° C. for 20 minutes. Subsequently, 17.65 g of 3,3′-4,4′-biphenyl tetracarboxylic acid dianhydride and 10 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Comparative Example 3

Under a stream of nitrogen, 10.27 g of APAB and 100 mL of dehydrated NMP were added to a 300 mL separable flask, and the mixture was stirred at 40° C. for 20 minutes. Subsequently, 13.24 g of 3,3′-4,4′-biphenyl tetracarboxylic acid dianhydride and 18 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

### Comparative Example 4

Under a stream of nitrogen, 5.42 g of ODA, 4.11 g of APAB, and 100 mL of dehydrated NMP were added to a 300 mL separable flask, and the mixture was stirred at 40° C. for 20 minutes. Subsequently, 13.24 g of 3,3′-4,4′-biphenyl tetracarboxylic acid dianhydride and 14 mL of dehydrated NMP were added thereto, and the resulting mixture was stirred at 80° C. The stirring was then stopped, and the mixture was allowed to cool to prepare a brown polyamic acid solution. The polyamic acid solution was applied to a 12 μm-thick copper foil (BHY-82F-HA-V2, manufactured by JX Nippon Mining & Metals Corporation) with an applicator (SA-201, manufactured by Tester Sangyo Co., Ltd.), and dried at 80° C. for 15 minutes and then at 120° C. for 25 minutes with a fan dryer. The dried product was further heated at 390° C. for 185 minutes in a vacuum heating furnace to thereby be imidized. As a result, a copper-clad laminate 1 sequentially including a polyimide film 2 and a copper foil 3 was obtained. Thereafter, the copper foil 3 was dissolved using an FeCl₃ solution, so that a polyimide film 2 was obtained.

The molar fractions of the diamine components in Examples and Comparative Examples are organized and described in Table 1.

<Evaluation of Polyimide Film>

The polyimide films 2 of Examples and Comparative Examples were evaluated with respect to the following items. The results are described in Table 1.

<Dielectric Loss Tangent of Polyimide Film after Immersion>

The polyimide film 2 was immersed in pure water for 24 hours. Then, the polyimide film 2 was taken out from the pure water, water droplets on the surface of the polyimide film 2 were wiped off, and the dielectric loss tangent (tan δ) of the polyimide film 2 was immediately measured by an SPDR dielectric resonator (manufactured by Agilent Technologies Japan, Ltd.).

<Coefficient of Thermal Expansion of Polyimide Film>

The polyimide film 2 was trimmed into a size of 4 mm wide and 40 mm long to produce a sample. The sample was set in a thermomechanical analyzer (TMAQ400, manufactured by TA Instruments), and heated from 0° C. to 200° C. at a heating rate of 2° C./min under a load of 0.01 N. Then, the sample was cooled from 200° C. to 0° C. at a cooling rate of 20° C./min. Thereafter, the sample was again heated from 0° C. to 200° C. at a heating rate of 2° C./min, and an average coefficient of thermal expansion of the sample at 100° C. to 200° C. was determined as a coefficient of thermal expansion.

### <Warpage of Copper-Clad Laminate During Heating>

The copper-clad laminate 1 in process, that is, the copper-clad laminate 1 before the copper foil 3 was removed, of each Examples and Comparative Examples was trimmed into a size of 4 mm wide and 50 mm long to produce a sample. The sample was heated in a 200° C. oven for 15 hours, and then allowed to cool. One end in the longitudinal direction of the sample was fixed to one surface of a flat plate, and how far (distance) the other end in the longitudinal direction thereof is from the one surface was measured.

The warpage was evaluated according to the following criteria. The results are described in Table 1.

Good: The distance between the other end and the flat plate was less than 13 mm.
Bad: The distance between the other end and the flat plate was 13 mm or more.

### [Table 1]

TABLE 1

| | | Example & Comparative Example | | | | | | | | | | |
|---|---|---|---|---|---|---|---|---|---|---|---|---|
| | | Comp. | Comp. | Comp. | Comp. | | | | | | | |
| | | Ex. 1 | Ex. 2 | Ex. 3 | Ex. 4 | Ex. 1 | Ex. 2 | Ex. 3 | Ex. 4 | Ex. 5 | Ex. 6 | Ex. 7 |
| Diamine | Molar fraction of | 80 | 0 | 0 | 0 | 60 | 40 | 20 | 20 | 50 | 10 | 10 |
| component | p-PDA (vs diamine | | | | | | | | | | | |
| | component) (%) | | | | | | | | | | | |
| | Molar fraction of | 20 | 100 | 0 | 60 | 20 | 20 | 40 | 60 | 30 | 35 | 55 |
| | ODA (vs diamine | | | | | | | | | | | |
| | component) (%) | | | | | | | | | | | |
| | Molar fraction of | 0 | 0 | 100 | 40 | 20 | 40 | 40 | 20 | 20 | 55 | 35 |
| | APAB (vs diamine | | | | | | | | | | | |
| | component) (%) | | | | | | | | | | | |
| Evaluation of | Dielectric loss tangent | 0.0138 | 0.0126 | 0.0146 | 0.0087 | 0.0070 | 0.0067 | 0.0070 | 0.0070 | 0.0060 | 0.0082 | 0.0075 |
| polyimide film | after immersion in | | | | | | | | | | | |
| | water (25° C.) (tanδ) | | | | | | | | | | | |
| | Coefficient of thermal | 21.69 | 46.43 | 25.31 | 45.8 | 23.05 | 23.71 | 37.74 | 43.94 | 29.15 | 27.72 | 37.89 |
| | expansion (ppm/K) | | | | | | | | | | | |
| Evaluation of | Evaluation of warpage | Good | Good | Bad | Bad | Good | Good | Good | Bad | Good | Good | Bad |
| copper-clad | | | | | | | | | | | | |
| laminate | | | | | | | | | | | | |

While the illustrative embodiments of the present invention are provided in the above description, such is for illustrative purpose only and it is not to be construed restrictively. Modification and variation of the present invention that will be obvious to those skilled in the art is to be covered by the following claims.

### INDUSTRIAL APPLICABILITY

The polyimide film is used in a metal-clad laminate.

### DESCRIPTION OF REFERENCE NUMERALS

1 metal-clad laminate
2 polyimide film
3 metal foil (copper foil)

1. A polyimide film being a reaction product of a diamine component and an acid dianhydride component, wherein
the diamine component comprises p-phenylenediamine; a first aromatic diamine; and a second aromatic diamine,
the first aromatic diamine and the second aromatic diamine are different from each other and represented by the following formula (1): 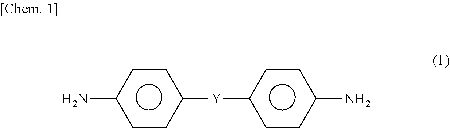
(where Y represents at least one selected from the group consisting of a single bond, —O—, —COO—, —S—, CH₂—, —CH(CH₃)—, —C(CH₃)₂—, —CO—, —SO₂—, —NH—, and —NHCO—),
in the diamine component, each of a molar fraction of the p-phenylenediamine, a molar fraction of the first aromatic diamine, and a molar fraction of the second aromatic diamine is 10% by mole or more and 70% by mole or less, and
the acid dianhydride component comprises an acid dianhydride comprising an aromatic ring.

2. The polyimide film according to claim 1, wherein the molar fraction of the p-phenylenediamine was 20% by mole or more.

3. The polyimide film according to claim 1, wherein the molar fraction of the first aromatic diamine or the second aromatic diamine was 50% by mole or less.

4. The polyimide film according to claim 2, wherein the molar fraction of the first aromatic diamine or the second aromatic diamine was 50% by mole or less.

5. A metal-clad laminate comprising:
a polyimide film according to claim 1; and
a metal foil disposed on one surface in a thickness direction of the polyimide film.

6. A metal-clad laminate comprising:
a polyimide film according to claim 2; and
a metal foil disposed on one surface in a thickness direction of the polyimide film.

7. A metal-clad laminate comprising:
a polyimide film according to claim 3; and
a metal foil disposed on one surface in a thickness direction of the polyimide film.

8. A metal-clad laminate comprising:
a polyimide film according to claim 4; and
a metal foil disposed on one surface in a thickness direction of the polyimide film.
